(19) United States
(12) Patent Application Publication
(10) Pub. No.: US 2026/0082875 A1
(43) Pub. Date: Mar. 19, 2026

(54) CARBON GAPFILL LAYER FORMATION

(71) Applicant: Applied Materials, Inc., Santa Clara, CA (US)

(72) Inventors: Lihua WU, Santa Clara, CA (US); Prashant Kumar KULSHRESHTHA, San Jose, CA (US); Chando PARK, Palo Alto, CA (US); Bharati NEELAMRAJU, Santa Clara, CA (US); Karthik Suresh MENON, Santa Clara, CA (US); Rajaram NARAYANAN, Santa Clara, CA (US); Liangfa HU, Santa Clara, CA (US); Yutao DONG, Santa Clara, CA (US); Lei HE, Santa Clara, CA (US); Kaili YU, Santa Clara, CA (US); Zaoyuan GE, Santa Clara, CA (US); Sungwon HA, Palo Alto, CA (US); Daemian Raj BENJAMIN RAJ, Fremont, CA (US)

(21) Appl. No.: 18/885,267

(22) Filed: Sep. 13, 2024

(51) Int. Cl. H01L 21/762; C23C 16/26; C23C 16/50; C23C 16/56; H01L 21/768

(52) U.S. Cl. CPC H10W 10/014; C23C 16/26; C23C 16/50; C23C 16/56; H10W 10/17; H10W 20/057

(57) ABSTRACT

A method for forming a gapfill layer, comprising: positioning a substrate in a processing volume of a processing chamber, forming a plurality of first gapfill layers in at least one feature disposed on the substrate, comprising, for each first gapfill layer included in the plurality of first gapfill layers: forming a layer in the at least one feature by flowing a first hydrocarbon precursor gas into the processing volume and etching the layer by flowing a first etchant gas into the processing volume, and forming a second gapfill layer in the at least one feature by co-flowing a second hydrocarbon precursor gas and a second etchant gas into the processing volume.

### BACKGROUND

### Field

Embodiments of the present disclosure generally relate to manufacture of semiconductor components and devices. More specifically, embodiments described herein provide methods for forming carbon gapfill layers on features of a semiconductor surface.

### Description of the Related Art

In semiconductor processing, devices are being manufactured with continually decreasing feature dimensions. Often, features utilized to manufacture devices at these advanced technology nodes include high aspect ratio structures, and it is often beneficial to fill gaps between circuit elements/structures with a variety of materials. Examples where gapfill material layers are utilized include filling shallow trench isolation (STI), horizontal interconnects, vias between adjacent metal layers, inter-metal dielectric layers (ILD), pre-metal dielectrics (PMD), passivation layers, patterning applications, etc. As the width between the structures shrinks, the gap between the structures often gets taller and narrower, making the gap more difficult to fill without the gapfill material being stuck on sidewalls and creating voids and weak seams. Furthermore, oftentimes a single device or substrate will have multiple gaps of varying widths (e.g., critical dimensions (CD)) and/or aspect ratios that will need to be filled with the gapfill material.

Conventional gapfill techniques often experience an overgrowth of material at the top of the gap before it has been completely filled. This can create a void or seam in the gap where the depositing material has been prematurely cut off by the overgrowth. This issue is sometimes referred to as “bread-loafing.” As device geometries shrink and thermal budgets are reduced, void-free and seam-free filling of high aspect ratio spaces becomes increasingly difficult due to limitations of existing deposition processes.

Therefore, improved techniques are needed for forming gapfill layers.

### SUMMARY

According to one or more embodiments, a method for forming a gapfill layer, comprising: positioning a substrate in a processing volume of a processing chamber, forming a plurality of first gapfill layers in at least one feature disposed on the substrate, comprising, for each first gapfill layer included in the plurality of first gapfill layers: forming a layer in the at least one feature by flowing a first hydrocarbon precursor gas into the processing volume and etching the layer by flowing a first etchant gas into the processing volume, and forming a second gapfill layer in the at least one feature by co-flowing a second hydrocarbon precursor gas and a second etchant gas into the processing volume.

A method for forming a gapfill layer, comprising: positioning a substrate in a processing volume of a processing chamber, forming a first gapfill layer in at least one feature disposed on the substrate, comprising: flowing a first hydrocarbon precursor gas into the processing volume, forming a layer in the at least one feature by generating a first RF plasma in the processing volume with the first hydrocarbon precursor gas and an RF source producing a first RF power, and etching the layer by flowing a first etchant gas into the processing volume, and forming a second carbon gapfill layer in the at least one feature, comprising: co-flowing a second hydrocarbon precursor gas and a second etchant gas into the processing volume, and generating a second RF plasma in the processing volume with the co-flowed second hydrocarbon precursor gas and second etchant gas and an RF source producing a second RF power, wherein the second RF power is less than the first RF power.

A method for forming a gapfill layer, comprising: positioning a substrate in a processing volume of a processing chamber, forming a plurality of first gapfill layers in at least one feature disposed on the substrate, comprising, for each first gapfill layer included in the plurality of the first gapfill layers: forming a layer in the at least one feature by flowing a first hydrocarbon precursor gas into the processing volume, and etching the layer by flowing a first etchant gas into the processing volume, and forming a second gapfill layer in the at least one feature by co-flowing a second hydrocarbon precursor gas and a second etchant gas into the processing volume; and forming a third gapfill layer in the at least one feature by flowing a third hydrocarbon precursor gas into the processing volume.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 schematically illustrates a cross-section of a process chamber, according to one or more embodiments.

FIG. 2 illustrates a partial schematic side view of a substrate, according to one or more embodiments.

FIG. 3 illustrates a method of forming a carbon gapfill layer on a substrate surface, according to one or more embodiments

FIG. 4A illustrates a partial schematic side view of a substrate during the deposition sub-operation of the dep-etch operation of the method of FIG. 3, according to one or more embodiments.

FIG. 4B illustrates a partial schematic side view of a substrate during the etch sub-operation of the dep-etch operation of the method of FIG. 3, according to one or more embodiments.

FIG. 4C illustrates a partial schematic side view of a substrate at the conclusion of the dep-etch operation of the method of FIG. 3, according to one or more embodiments.

FIG. 4D illustrates a partial schematic side view of the substrate at the conclusion of the first one-shot deposition operation of the method of FIG. 3, according to one or more embodiments.

FIG. 4E illustrates a partial schematic side view of the substrate at the conclusion of the second one-shot deposition operation of the method of FIG. 3, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to manufacture of semiconductor components and devices. More specifically, embodiments described herein provide methods for forming gapfill layers.

The following disclosure describes techniques for forming layers of a gapfill material (e.g., carbon) in features (e.g., high aspect-ratio trenches) formed on a substrate surface or a material layer disposed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals (e.g., tungsten), metal nitrides (e.g., TiN), metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface.

In addition to film processing directly on the surface of the substrate itself, in the present disclosure, any of the processing steps disclosed may also be performed on an intermediate layer formed on the substrate, as disclosed in more detail below. In various embodiments, the term “substrate surface” is intended to include such an intermediate layer as the context indicates. Thus, for example, where a film/layer or partial film/layer has been deposited onto a substrate surface, the exposed surface of the newly deposited film/layer may be considered the substrate surface.

Carbon-based film deposition has been used to provide gapfill material layers during semiconductor processing through vapor deposition process techniques, such as CVD or plasma enhanced chemical vapor deposition (PECVD). Embodiments described herein will be described below in reference to a plasma enhanced chemical vapor deposition (PECVD) process that can be carried out using any suitable thin film deposition.

Current gapfill methods result in voids in the gapfill affecting later semiconductor processes and, ultimately, semiconductor device performance. In some instances, carbon deposition within substrate trenches leaves voids in the gapfill. For instance, the gapfill layer may prematurely close-off (or “pinch-off”) the top portion of the trenches before the gapfill material can fill the trenches, leaving voids in portions of the gapfill in the trenches.

Embodiments of the present disclosure provide techniques for performing a multi-step carbon gapfill process. After placing a substrate including at least one feature in a process chamber, a first carbon gapfill layer is formed by conducting a dep-etch operation wherein a hydrocarbon precursor gas, and optionally a co-flow gas, is used to form a first carbon layer in one or more features of the substrate and an etchant gas is used to selectively etch the first carbon layer. The dep-etch operation may be repeated a number of times to sufficiently fill the bottom portion of the trenches with the first carbon gapfill layer. After the one or more dep-etch operations, a second carbon gapfill layer is formed by a first one-shot deposition operation, wherein a hydrocarbon precursor gas and an etchant gas are co-flowed to fill remaining voids. Optionally, a third carbon gapfill layer is formed by a second one-shot deposition operation, wherein the hydrocarbon precursor gas is used to fill the remainder of the trenches with the carbon.

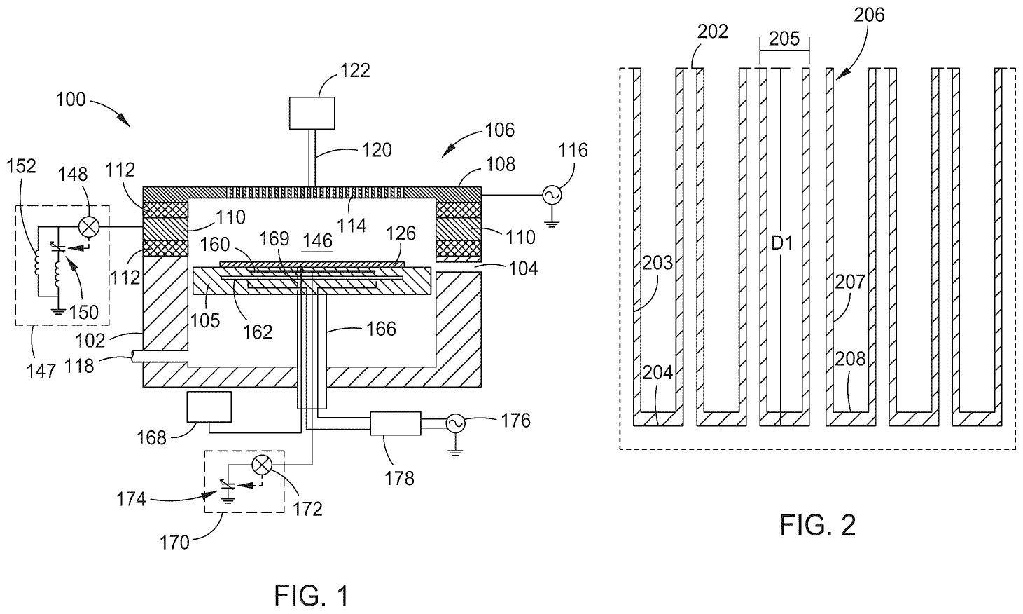

FIG. 1 illustrates a cross-section of a process chamber 100, such as a plasma enhanced chemical vapor deposition (PECVD) chamber. While the process chamber 100 is described as a PECVD system, any process chamber may fall within the scope of the embodiments, including other plasma deposition chambers.

The process chamber 100 includes a chamber body 102, a lid assembly 106, and a substrate support 105. The lid assembly 106 is disposed at an upper end of and is supported by the chamber body 102, and the substrate support 105 is at least partially disposed within the chamber body 102. The chamber body 102, lid assembly 106, and substrate support 105 together define an interior processing volume 146 within the process chamber 100 in which a substrate 126 may be processed. The interior processing volume 146 may be accessed through a port 104 formed in the chamber body 102 that facilitates transfer of a substrate into and out of the processing volume 146 of the process chamber 100.

The lid assembly 106 includes a gas distributor 108, a modulation electrode 110, and insulators 112. In some embodiments, the modulation electrode 110 is optional. The insulator 112, which may be a dielectric material such as a ceramic or metal oxide (e.g., aluminum oxide and/or aluminum nitride), contacts the modulation electrode 110 and separates the modulation electrode 110 electrically and thermally from the gas distributor 108 and from the chamber body 102. The gas distributor 108 (e.g., showerhead) has passages 114 therethrough for admitting process gas into the processing volume 146. A pair of insulators (e.g., annular insulators) are disposed between the gas distributor 108 and the modulation electrode 110. The modulation electrode 110 is annular and circumscribes the processing volume 146.

Process gases may be provided through the conduit 120 from one or more gas sources 122 to be introduced into the process chamber 100. The processing gas from the conduit 120 enters the processing volume 146 through the passages 114 in the gas distributor 108 such that the processing gas is uniformly distributed in the processing volume 146. In some embodiments, the passages 114 in the gas distributor 108 may be radially distributed, and gas flow to each of the passages 114 may be separately controlled to further facilitate gas uniformity within the processing volume 146.

The processing gases can be evacuated from the interior processing volume 146 through an outlet 118 which may be located at any convenient location along the chamber body 102. In some embodiments, the outlet 118 may be associated with a vacuum pump (not shown) fluidly coupled to the interior processing volume 146. The vacuum pump may be part of the gas and pressure control system of the processing system 100. The gas and pressure control system maintains the process volume at a pressure of about 3 Torr to about 50 Torr.

In some embodiments, portions of the gas distributor 108 may be heated using a resistive heater (not shown) or thermal fluid disposed in a conduit (not shown) through a portion of the gas distributor 108 or otherwise in direct contact or thermal contact with the gas distributor 108. The conduit may be disposed through an edge portion of the gas distributor 108 to avoid disturbing the gas flow function of the gas distributor 108. Heating the edge portion of the gas distributor 108 may be useful to reduce the tendency of the edge portion of the gas distributor 108 to be a heatsink within the chamber 100.

In some embodiments, the walls of the chamber body 102 may also be heated to similar effect. Heating the chamber surfaces exposed to the plasma also minimizes deposition, condensation, and/or reverse sublimation on the chamber surfaces, reducing the cleaning frequency of the chamber and increasing mean cycles per clean. Higher temperature surfaces also promote dense deposition that is less likely to produce particles that fall onto a substrate. Thermal control conduits with resistive heaters and/or thermal fluids (not shown) may be disposed through the chamber walls to achieve thermal control of the chamber walls. Temperature of all surfaces may be controlled by a controller.

In some embodiments, the gas distributor 108 may be coupled to a RF power source 116, such as a RF generator, as shown in FIG. 1. In other embodiments, the gas distributor 108 may be coupled to ground. The RF power source 116 is electrically connected to the gas distributor 108 and is configured to apply a RF potential to the gas distributor 108 to facilitate the generation of plasma in the interior processing volume 146.

In some embodiments, the RF power source 116 may be a high frequency RF power source (“HFRF power source”) capable of generating an HFRF power (e.g., at a frequency of about 10 MHz to about 40 MHz, e.g., about 20 MHz to about 22 MHz, about 22 MHz to about 24 MHz, about 24 MHz to about 26 MHz, about 26 MHz to about 28 MHz, or about 28 MHz to about 30 MHz). In other embodiments, the RF power source 116 may be a low frequency RF power source (“LFRF power source”) capable of generating an LFRF power (e.g., at a frequency of about 300 kHz). The LFRF power source can provide both low frequency generation and fixed match elements. The HFRF power source can be designed for use with a fixed match and can regulate the power delivered to the load, eliminating concerns about forward and reflected power. In further embodiments, an additional power source (not shown) may be added with the RF power source 116 to provide a dual RF power source to the process chamber 100.

The modulation electrode 110 may be coupled to a tuning circuit 147 that controls an impedance of an electrical path from the modulation electrode 110 to an electrical ground. The tuning circuit 147 comprises an electronic sensor 148 and an electronic controller, which may be a variable capacitor 150 as shown that is controllable by the electronic sensor 148. The tuning circuit 147 may be an LLC circuit comprising one or more inductors 152. The electronic sensor 148 may be a voltage or current sensor, and may be coupled to the variable capacitor 150 to afford a degree of closed-loop control of plasma conditions inside the interior processing volume 146. In some embodiments, the tuning circuit 147 may be any circuit that features a variable or controllable impedance under the plasma conditions present in the processing volume 146 during processing

The substrate support 105 may be disposed within the process chamber 100. The substrate support 105 may support a substrate 126 during processing. A first electrode 160 and a second electrode 162 are disposed in and/or on the substrate support 105. Further, in some embodiments, a heater element (not shown) may be embedded in the substrate support 105. The heater element can be operable to controllably heat the substrate support 105 and the substrate 126 positioned thereon to a target temperature, such as to maintain the substrate 126 at a temperature in a range from about 200 degrees Celsius to about 700 degrees Celsius.

The substrate support 105 is coupled to a shaft 166 for support. The shaft 166 can provide a conduit from a gas source 168 and electrical and temperature monitoring leads (not shown) between the substrate support 105 and other components of the process chamber 100. In some examples, a purge gas may be provided from the gas source 168 to the backside of the substrate 126 through one or more purge gas inlets 169 connected to the substrate support 105. The purge gas flowed toward the backside of the substrate 126 can help prevent particle contamination caused by deposition on the backside of the substrate 126. The purge gas may also be used as a form of temperature control to cool the backside of the substrate 126. Although not illustrated, the shaft 166 may be coupled to an actuator (not shown) which extends through a centrally-located opening formed in a bottom of the chamber body 102. The actuator may be flexibly sealed to the chamber body 102 by bellows (not shown) that prevent vacuum leakage from around the shaft 166. The actuator can allow the substrate support 105 to be moved vertically within the chamber body 102 between a process position and a lower, transfer position. The transfer position is slightly below the port 104 in the chamber body 102. In operation, the substrate support 105 may be elevated to a position in close proximity to the lid assembly 106 for processing.

The first electrode 160 may be embedded within the substrate support 105 or coupled to a surface of the substrate support 105. The first electrode 160 may be a plate, a perforated plate, a mesh, a wire screen, or any other distributed arrangement. The first electrode 160 may be a tuning electrode, and may be coupled to a tuning circuit 170. The tuning circuit 170 may have an electronic sensor 172 and an electronic controller, such as a variable capacitor 174 electrically connected between the first electrode 160 and an electrical ground. The electronic sensor 172 may be a voltage or current sensor, and may be coupled to the variable capacitor 174 to provide further control over plasma conditions in the interior processing volume 146.

The second electrode 162, which may be a bias electrode and/or an electrostatic chucking electrode, may be coupled to the substrate support 105. The second electrode 162 may be coupled to a bias power source 176 through an impedance matching circuit 178. The bias power source 176 may be DC power, pulsed DC power, RF power, pulsed RF power, or a combination thereof.

In operation, the substrate 126 is disposed on the substrate support 105, and process gases are flowed through the lid assembly 106 according to any desired flow plan. Electric power is coupled to the gas distributor to establish a plasma in the interior processing volume 146 between the gas distributor 108 and the substrate support 105.

Upon energizing a plasma in the interior processing volume 146, a potential difference is established between the plasma and the modulation electrode 110. A potential difference is also established between the plasma and the first electrode 160. The variable capacitors 150 and 174 may then be used to adjust the impedances of the paths to an electrical ground represented by the tuning circuits 147 and 170. A set point may be delivered to the tuning circuits 147 and 170 to provide independent control of the plasma density uniformity from center to edge and deposition rate. The electronic sensors may adjust the variable capacitors to maximize deposition rate and minimize thickness non-uniformity independently. The components implemented to control temperature and uniformity of the plasma, among other, can permit deposition of a highly conformal layer on a substrate being processed, even within small gaps.

Other deposition chambers may also benefit from the present disclosure and the parameters listed above may vary according to the particular deposition chamber used for the carbon gapfill process described herein.

In general, the following exemplary PECVD process parameters may be used for the carbon gapfill layer formation process described herein. The processing temperature may range from a temperature inside the process chamber of about 200° C. to about 1000° C. (e.g., about 300° C. to about 800° C.). The chamber pressure may range from about 1 Torr to about 50 Torr (e.g., about 10 Torr to about 30 Torr). The RF power may be about 200 Watts (W) to about 1500 W at any RF frequency.

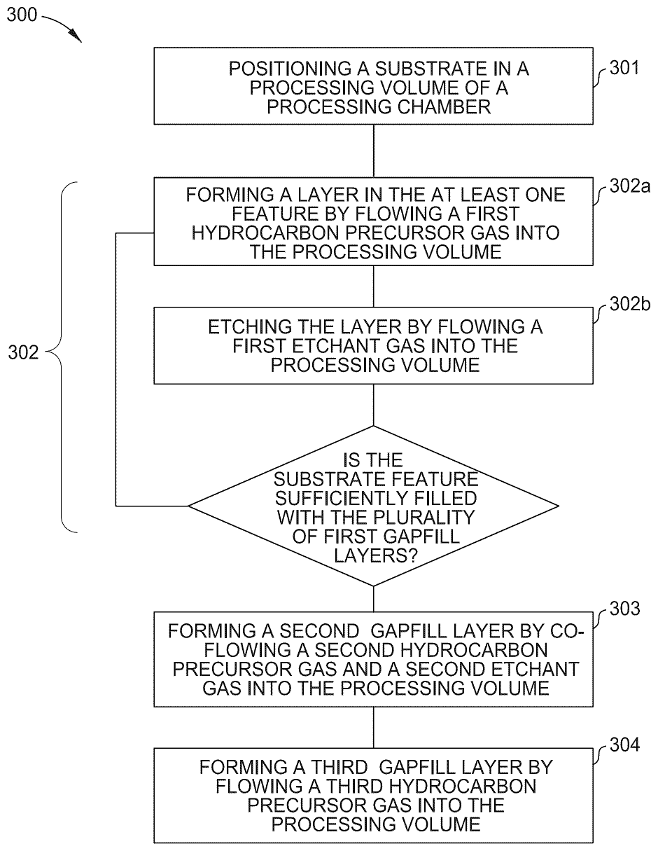

FIG. 2 illustrates a partial schematic side view of the substrate 126, according to one or more embodiments. The substrate 126 includes substrate surface features 201 (e.g., trenches). The trenches 201 are formed in the surface 202 of the substrate 126 and include sidewalls 203, a bottom surface 204, a depth (D1), and a critical dimension (CD) 205 defining the opening in the surface 202 of the substrate 126. The trenches 201 include an aspect ratio defined as D1/CD. The trenches may have a high aspect ratio. That is, the CD 205 of the trenches 201 may be smaller than the depth D1 of the trenches. In some embodiments, the aspect ratio of the trenches 201 may be about 5:1 to about 120:1, such as about 50:1 to about 100:1. In some embodiments, the aspect ratio of the trenches 201 may be greater than 80. For instance, the CD 205 may be about 50 nanometers (nm) to about 200 nm and the depth D1 of the trenches 201 may be about 1 micrometer (um) to about 12 um.

While the substrate 126 is shown as a single body, the substrate may contain one or more materials used in forming semiconductor devices such as metal contacts, trench isolations, gates, bitlines, or any other interconnect features.

The substrate 126 may be any substrate or material surface upon which film processing is performed. For example, the substrate 126 may be a material such as crystalline silicon, silicon oxide, silicon oxynitride, silicon nitride, strained silicon, silicon germanium, tungsten, titanium nitride, doped or undoped polysilicon, doped or undoped silicon wafers and patterned or non-patterned wafers, silicon on insulator (SOI), carbon doped silicon oxides, silicon nitrides, doped silicon, germanium, gallium arsenide, glass, sapphire, low-k dielectrics, and combinations thereof.

The substrate 126 may comprise one or more metal layers, one or more dielectric materials, semiconductor material, and combinations thereof utilized to fabricate semiconductor devices. For example, the substrate 126 may include an oxide material, a nitride material, a polysilicon material, or the like, depending upon application. In the presently illustrated embodiment, the substrate 126 includes a metal layer 206 including titanium nitride (TiN) lining the trenches 201. The metal layer 206 lines sidewalls 203 and bottom surface 204 of the trenches 201. Therefore, the metal layer 206 includes sidewalls 207 and a bottom surface 208.

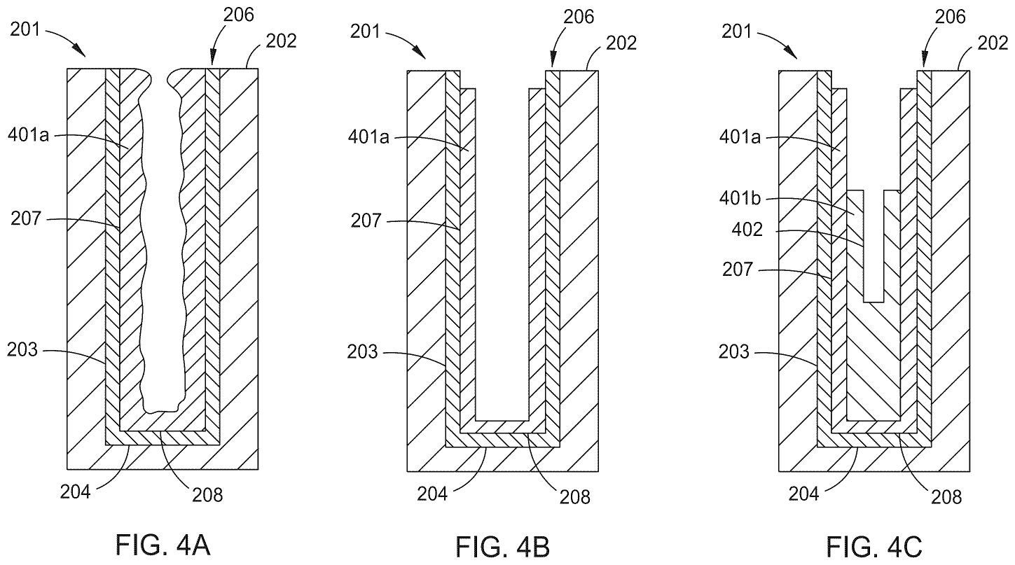

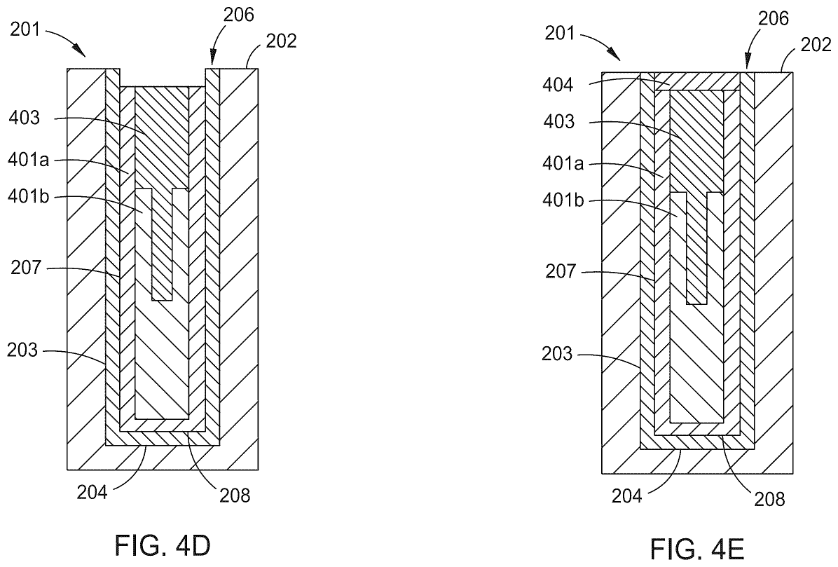

FIG. 3 illustrates a method 300 for performing gapfill in a feature of a substrate. For instance, method 300 includes performing gapfill in a high-aspect ratio trench (e.g. trench 201 of FIGS. 2 and 4A-4E), formed on a substrate (e.g. substrate 126 of FIGS. 1-2 and 4A-4E). FIGS. 4A-4E depict schematic cross-sectional views of the substrate 126 illustrating the carbon gapfill layer formation process according to method 300.

At operation 301, the substrate 126 including a substrate feature, such as trench 201, is placed in a processing volume (e.g. processing volume 146 of FIG. 1) of a process chamber (e.g. process chamber 100 of FIG. 1) for processing. In some embodiments, the trench 201 may be lined with a metal layer 206. In some embodiments, the metal layer 206 is already formed in the trench 201 when the substrate 126 is placed in the processing volume. In some embodiments, the metal layer 206 is formed in the trench 201 after the substrate 126 is placed in the processing volume. Although FIGS. 4A-4E illustrate the substrate 126 having a single trench 201 for illustrative purposes, those skilled in the art will understand there can be more than one trench 201 with the same or different CDs 205 and depths D1.

In some embodiments, the substrate 126 may be transferred into the process chamber and onto a substrate support (e.g. substrate support 105 of FIG. 1) by any suitable means, such as by substrate transfer port. The substrate support can be adjusted from a transfer position to a processing position by an actuator (not shown).

At operation 302, a first carbon gapfill layer 401 is formed in a bottom portion of the trench 201 utilizing a deposition-etch loop (hereinafter “dep-etch operation”). The dep-etch operation includes a deposition sub-operation utilizing a hydrocarbon precursor, and optionally, a co-flow gas (operation 302a) and an etch sub-operation (operation 302b) utilizing an etchant flow. Operation 302 is shown in FIGS. 4A-4C. Operation 302 is repeated (e.g., looped) a number of times. For instance, operation 302 may be repeated more than 10 times, such as about 10 times to about 200 times, or more than 50 times, or about 50 times to about 150 times.

As will be discussed herein, the first carbon gapfill layer 401 comprises multiple carbon layers 401a, 401b, based on the number of times operation 302 is repeated.

Operation 302 may be repeated until the first carbon gapfill layer 401 has sufficiently filled the bottom of the trench 201, as shown in FIG. 4C. For instance, operation 302 may be repeated until the bottom portion of the trench 201 has been filled at least about 60%, for instance about 60% to about 95% with the first carbon gapfill layer 401, such as more than 60% or more than 80%. In some embodiments, the operation 302 may be repeated until the bottom portion of the trench 201 has been filled about 80% to about 90% with the first carbon gapfill layer 401.

Each iteration of operation 302 includes sub-operation 302a for an amount of time and sub-operation 302b for an amount of time. It has been observed that, as the time ratio of sub-operation 302a to sub-operation 302b is decreased, the presence of voids in the first carbon gapfill layer 401 is decreased. In some embodiments, the time ratio of sub-operation 302a to sub-operation 302b may be about 1:1 to about 4:1, such as 1.5:1 to about 3:1.

At sub-operation 302a, a liner-like carbon layer 401a is formed. Operation 302a is illustrated in FIG. 4A. During operation 302a, a hydrocarbon precursor gas, and optionally a co-flow gas, is used to form the liner-like carbon layer 401a. The hydrocarbon precursor gas, and optionally the co-flow gas, may be flowed from one or more gas sources (e.g. one or more gas sources 122 of FIG. 1) into the processing volume through a gas distributor (e.g. gas distributor 108 of FIG. 1) to provide a deposition species for forming the carbon layer 401a.

In some embodiments, the hydrocarbon precursor gas includes a hydrocarbon compound having a general formula CₓH_{y}, where x has a range of 1 and 20, and y has a range of 1 and 20. Suitable carbon compounds include, for example, methane (CH₄), acetylene (C₂H₂), ethylene (C₂H₄), ethane (C₂H₆), butylenes (C₄H₈), cyclobutane (C₄H₈), and methylcyclopropane (C₄H₈). In some embodiments, the hydrocarbon precursor is acetylene (C₂H₂). In some embodiments, the co-flow gas is hydrogen gas (H₂).

During sub-operation 302a, RF plasma is generated in the processing volume to form the carbon layer 401a on the bottom surface 208 and the sidewalls 207 of the metal layer 206. The plasma may be formed by capacitive means, and may be energized by coupling RF power into the processing gas mixture provided by an RF source (e.g. RF source 116 of FIG. 1). The RF source operates at an RF frequency and produces an RF power. In some embodiments, the RF frequency may be about 10 MHz to about 40 MHz. The RF power may be about 200 W to about 1000 W, such as about 400 W to about 800 W. In some embodiments, the RF power may be about 400 W.

Occasionally, the liner-like carbon layer 401a may include a non-uniform sidewall, as shown in FIG. 4A. A non-uniform sidewall may lead to premature closing of the carbon layer 401a potentially leaving a void in the first carbon gapfill layer 401 at or near the bottom portion of the trench 201.

At sub-operation 302b, the liner-like carbon layer 401a formed during sub-operation 302a is etched. Sub-operation 302b is illustrated in FIG. 4B. In various embodiments, sub-operation 302b is performed to re-open the carbon layer 401a and polish the carbon layer 401a by selectively etching a top portion of the carbon layer 401a and the sidewalls of the carbon layer 401a. Selectively etching the top portion and sidewalls of the carbon layer 401a allows subsequent deposition sub-operations 302a to sufficiently fill the bottom portion of the trench 201 with subsequent carbon layers 401b to form the first carbon gapfill layer 401, as shown in FIG. 4C. Selectively etching the top portion and sidewalls of the carbon layers 401a also allows subsequent deposition operations, such as operations 303 and 304, to fill the trench 201 while minimizing voids.

During sub-operation 302b, an etchant, such as hydrogen gas (H₂), is flowed into the processing volume to etch the carbon layer 401a formed in sub-operation 302a. The etchant polishes the carbon layer 401a to ensure that the top portion of the carbon layer 401a is open and the sidewalls of the carbon layer 401a are smooth, as shown in FIG. 4B. Opening the top portion of the carbon layer 401a and polishing the sidewalls of the carbon layer 401b allows subsequent loops of sub-operation 302a to sufficiently fill the bottom portion of the trench 201 with subsequent carbon layers 401b while minimizing voids. During sub-operation 302b, the RF source operates at an RF frequency and produces an RF power. In some embodiments, the RF frequency may be about 10 MHz to about 40 MHz. The RF power may be about 200 W to about 1000 W, such as about 400 W to about 800 W. In some embodiments, the RF power may be about 800 W during sub-operation 302b.

As discussed above, sub-operation 302a and sub-operation 302b may be repeated a number of times. As such, multiple carbon layers 401a and 401b build upon one another within the trench 201 to form first carbon gapfill layer 401. While only two carbon layers 401a and 401b are shown in FIG. 4C for illustrative purposes, it is understood that any number of loops may occur to form any number of carbon layers in first carbon gapfill layer 401.

At the conclusion of the predetermined number of loops of operation 302, the first carbon gapfill layer 401 may sufficiently fill the bottom portion of the trench 201, as shown in FIG. 4C. For instance, the first carbon gapfill layer 401 may fill 60% to 95% of the bottom portion of the trench 201 before moving onto subsequent operations of method 300.

In some embodiments, the carbon gapfill layer 401 formed at the end of the predetermined number of loops of operation 302 may include one or more voids 402 in the bottom portion of the trench 201. However, the one or more voids 402 may remain unclosed so that subsequent operations in method 300, such as operation 303 and (optionally) operation 304, may be used to fill the one or more voids 402 and the top portion of the trench 201.

At operation 303, a second gapfill layer 403 is formed at operation 303 utilizing a first one-shot deposition operation. Operation 303 is illustrated in FIG. 4D. During operation 303, a carbon precursor, such as C₂H₂, and an etchant, such as H₂, are co-flowed into the processing volume to form the second carbon gapfill layer 403 on top of the first carbon gapfill layer 401.

During operation 303, RF plasma is generated in the processing volume to form the second carbon gapfill layer 403 atop the first carbon gapfill layer 401 formed in operation 302 to fill at least some of the unfilled portions of the trench 201. The plasma may be formed by capacitive means, and may be energized by coupling RF power into the processing gas mixture provided by the RF source. The RF source may operate at an RF frequency and produce an RF power. In some embodiments, RF frequency may be about 27 MHz. In some embodiments, the RF power produced in operation 303 may be about equal to the RF power produced at operations 302a and 302b. In some embodiments, the RF power produced in operation 303 may be less than the RF power produced at operation 302a. In some embodiments, the RF power may be about 200 W to about 1000 W, such as about 400 W to about 600 W. In some embodiments, the RF power during operation 303 may be about 400 W. Lower RF power in operation 303 may produce a slower deposition rate. It has been observed that a slower deposition rate may minimize voids and gaps in the second carbon gapfill layer 403 formed during operation 303. The slower deposition rate allows the subsequent second carbon gapfill layer 403 to grow more slowly from the sidewalls 203 of the trench 201, the sidewalls 207 of the metal layer 206, and the sidewalls of the first carbon gapfill layer 401 formed in operation 302.

Optionally, a third carbon gapfill layer 404 may be formed on top of the second gapfill layer 403 at operation 304 utilizing a second one-shot deposition. operation 304 may be required if any portion of the trench 201 remains unfilled by the first carbon gapfill layer 401 and the second carbon gapfill layer 403 formed during operations 302 and 303 such as a top portion of the trenches 201.

Operation 304 is illustrated in FIG. 4E. During operation 304, a carbon precursor, such as C₂H₂, is flowed into the processing volume via the one or more gas sources. The hydrocarbon precursor is used to deposit the third carbon gapfill layer 404 into the trench 201 to fill any remaining gaps, voids, or space within the trench 201 left unfilled by operations 302 and 303.

During operation 304, RF plasma is generated in the processing volume to form the third carbon gapfill layer 404 atop the first carbon gapfill layer 401 and the second carbon gapfill layer 403. In some embodiments, the plasma may be formed by capacitive means and may be energized by coupling RF power into the processing gas mixture provided by the RF source operating at an RF frequency. The RF source operates at an RF frequency and produces an RF power. The RF frequency may be about 27 MHz. In some embodiments, the RF power produced in operation 304 may be about equal to the RF power produced at operations 302a, 302b, and 303. In some embodiments, the RF power produced in operation 304 may be less than the RF power produced at operations 302a, 302b, and 303. In some embodiments, the RF power may be about 200 W to about 1000 W, such as about 400 W to about 600 W. In some embodiments, the RF power during operation 303 may be about 400 W. Lower RF power in operation 303 may produce a slower deposition rate.

During the method 300, the process chamber may be maintained at a certain temperature and pressure to maintain a liner-like deposition of the carbon layer 401a within the trench 201. In some embodiments, the chamber may be maintained at a temperature of about 200° C. to about 1000° C. (e.g., about 300° C. to about 800° C.). In some embodiments, the temperature is maintained at about 500° C. and 700° C. It has been observed that maintaining a high temperature, such as about 500° C. and 700° C., the carbon gapfill layers 401, 403, 404 formed during the method 300 experience less shrinkage in subsequent substrate processes leading to better substrate performance. In some embodiments, the process chamber may be maintained at a pressure 1 Torr to about 50 Torr (e.g., about 10 Torr and about 30 Torr).

Certain details are set forth in the following description and figures to provide a thorough understanding of various embodiments of the disclosure. Other details describing well-known structures and systems often associated with plasma processing are not set forth in the following disclosure to avoid unnecessarily obscuring the description of the various embodiments.

What is claimed is:

1. A method for forming a gapfill layer, comprising:
positioning a substrate in a processing volume of a processing chamber;
forming a plurality of first gapfill layers in at least one feature disposed on the substrate, comprising, for each first gapfill layer included in the plurality of first gapfill layers:
forming a layer in the at least one feature by flowing a first hydrocarbon precursor gas and a co-flow gas into the processing volume; and
etching the layer by flowing a first etchant gas into the processing volume; and
forming a second gapfill layer in the at least one feature by co-flowing a second hydrocarbon precursor gas and a second etchant gas into the processing volume.

2. The method of claim 1, wherein at least one of the first hydrocarbon precursor gas and the second hydrocarbon precursor gas comprises acetylene (C₂H₂).

3. The method of claim 1, wherein at least one of the first etchant gas and the second etchant gas comprises hydrogen gas (H₂).

4. The method of claim 1, wherein the co-flow gas comprises hydrogen gas (H₂).

5. The method of claim 1, wherein the first hydrocarbon precursor gas and the second hydrocarbon precursor gas are the same.

6. The method of claim 1, wherein the plurality of first gapfill layers comprises at least 50 layers.

7. The method of claim 6, wherein the at least one feature is filled at least about 60% by volume with the plurality of first gapfill layers.

8. The method of claim 1, wherein the at least one feature comprises a trench having an aspect ratio of about 50:1 to about 100:1.

9. The method of claim 8, wherein the trench includes a liner comprising titanium nitride (TiN).

10. The method of claim 1, wherein the processing chamber is maintained at a temperature of about 500° C. to about 700° C.

11. The method of claim 1, wherein the processing chamber is maintained at a pressure of about 10 Torr to about 30 Torr.

12. The method of claim 1, wherein:
the layer is formed during a first period of time;
the layer is etched during a second period of time; and
a ratio of the first period of time to the second period of time is about 1:1 to about 4:1.

13. The method of claim 1, further comprising:
forming a third gapfill layer on the second gapfill layer by flowing a third hydrocarbon precursor gas into the processing chamber.

14. A method for forming a gapfill layer, comprising:
positioning a substrate in a processing volume of a processing chamber;
forming a first gapfill layer in at least one feature disposed on the substrate, comprising:
flowing a first hydrocarbon precursor gas into the processing volume;
forming a layer in the at least one feature by generating a first RF plasma in the processing volume with the first hydrocarbon precursor gas and an RF source producing a first RF power; and
etching the layer by flowing a first etchant gas into the processing volume; and
forming a second carbon gapfill layer in the at least one feature, comprising:
co-flowing a second hydrocarbon precursor gas and a second etchant gas into the processing volume; and
generating a second RF plasma in the processing volume with the co-flowed second hydrocarbon precursor gas and second etchant gas and an RF source producing a second RF power, wherein the second RF power is less than the first RF power.

15. The method of claim 14, wherein the first hydrocarbon precursor gas and the second hydrocarbon precursor gas are the same.

16. The method of claim 14, wherein the first etchant gas and the second etchant gas are the same.

17. The method of claim 14, wherein the at least one feature comprises a trench, and wherein the trench has an aspect ratio of about 50:1 to about 120:1.

18. A method for forming a gapfill layer, comprising:
positioning a substrate in a processing volume of a processing chamber;
forming a plurality of first gapfill layers in at least one feature disposed on the substrate, comprising, for each first gapfill layer included in the plurality of the first gapfill layers:
forming a layer in the at least one feature by flowing a first hydrocarbon precursor gas into the processing volume; and
etching the layer by flowing a first etchant gas into the processing volume; and
forming a second gapfill layer in the at least one feature by co-flowing a second hydrocarbon precursor gas and a second etchant gas into the processing volume; and
forming a third gapfill layer in the at least one feature by flowing a third hydrocarbon precursor gas into the processing volume.

19. The method of claim 18, wherein the processing chamber is maintained at a temperature of about 500° C. to about 700° C.

20. The method of claim 18, wherein the processing chamber is maintained at a pressure of about 10 Torr to about 30 Torr.
